(19) United States
(12) Patent Application Publication
(10) Pub. No.: US 2016/0351608 A1
(43) Pub. Date: Dec. 1, 2016

(54) CHIP PACKAGE AND METHOD OF MANUFACTURING THE SAME

(71) Applicant: XINTEC INC., Taoyuan City (TW)

(72) Inventors: Yu-Lung HUANG, Taoyuan City (TW); Chi-Chang LIAO, Zhubei City (TW); Tsang-Yu LIU, Zhubei City (TW)

(21) Appl. No.: 15/163,625

(22) Filed: May 24, 2016

Related U.S. Application Data
(60) Provisional application No. 62/167,533, filed on May 28, 2015.

(51) Int. Cl. H01L 27/146

(52) U.S. Cl. CPC H01L 27/14623; H01L 27/14636; H01L 27/14698; H01L 27/14687

(57) ABSTRACT

A chip package includes a substrate, a conductive layer and a plurality of thermal dissipation connections. The substrate includes a light-sensing region and has an upper surface and a lower surface opposite to each other. The conductive layer is disposed at the lower surface of the substrate and includes a light-shielding dummy conductive layer substantially aligned with the light-sensing region. The thermal dissipation connections are disposed beneath the lower surface of the substrate.

### RELATED APPLICATIONS

This application claims priority to US Provisional Application Serial Number 62/167,533, filed May 28, 2015, which is herein incorporated by reference.

### BACKGROUND

Field of the Invention

The present invention relates to a chip package and a manufacturing method thereof.

Description of Related Art

With increasing demands of electronic or photoelectric products such as digital camera, cell phone with image-taking function, bar code reader, and monitors, semiconductor technology has developed quite quickly and the size of a semiconductor chip has a trend of miniaturization, and functions of which becomes more complex. Most semiconductor chips are generally disposed in a package for demands of efficacy, which improves operation stability. However, existed chip packages still have problems, such as light leakage and bad thermal dissipation, needed to be solved. Therefore, a novel chip package is needed to over the aforementioned problems.

### SUMMARY

The present invention provides a chip package, which includes a substrate, a conductive layer, and multiple thermal dissipation connections. The substrate includes a light-sensing region. The conductive layer includes a light-shielding dummy conductive layer substantially aligned with the light-sensing region to avoid light leakage. The thermal dissipation connections are disposed at a lower surface of the substrate to assist thermal dissipation. Therefore, the chip package in the present disclosure can solve the aforementioned problems such as light leakage and bad thermal dissipation.

The chip package provided by the present invention includes a substrate, a conductive layer, and multiple thermal dissipation connections. The substrate includes a light-sensing region and has an upper surface and a lower surface opposite to each other. The conductive layer is disposed at the lower surface of the substrate and includes a light-shielding dummy conductive layer substantially aligned with the light-sensing region. The multiple thermal dissipation connections are disposed underneath the lower surface of the substrate.

According to an embodiment of the present disclosure, the chip package further includes a light-receiving structure disposed at the upper surface of the light-sensing region of the substrate.

According to an embodiment of the present disclosure, the thermal dissipation connections are floating and are disposed underneath the light-shielding dummy conductive layer.

According to an embodiment of the present disclosure, the thermal dissipation connections are in contact with the light-shielding dummy conductive layer.

According to an embodiment of the present disclosure, the chip package further includes an insulating layer sandwiched between the substrate and the conductive layer.

According to an embodiment of the present disclosure, the conductive layer further includes a redistribution layer and a light-shielding dummy conductive layer separated from each other.

According to an embodiment of the present disclosure, the chip package further includes multiple connective connections disposed underneath the redistribution layer and electrically connected to the redistribution layer.

According to an embodiment of the present disclosure, a height of each top surface of the thermal dissipation connections is substantially equal to a height of each top surface of the conductive connections.

According to an embodiment of the present disclosure, the thermal dissipation connections are solder balls.

According to an embodiment of the present disclosure, the thermal connections are arranged in a solder ball array.

The present disclosure further provides a method of manufacturing a chip package, the method includes: providing a wafer including a substrate and at least a conductive pad region, the substrate includes multiple light-sensing regions and has an upper surface and a lower surface opposite to each other, the conductive pad region is disposed at the upper surface of the substrate out of the light-sensing regions; removing a portion of the substrate to form a through via exposing the conductive pad region; forming an insulating layer underneath the lower surface of the substrate and covering a sidewall of the through via; forming multiple light-shielding dummy conductive layers and a redistribution layer separated from each other and underneath the insulating layer, the light-shielding dummy conductive layers are substantially aligned with the light-receiving structure respectively, the redistribution layer is electrically connected to the conductive pad region; and forming multiple thermal dissipation connections underneath the light-shielding dummy conductive layers, the redistribution layer, or a combination thereof.

According to an embodiment of the present disclosure, the thermal dissipation connections are floating and are formed underneath the light-shielding dummy conductive layers.

According to an embodiment of the present disclosure, the method of manufacturing the chip package further includes forming a conductive connection underneath the redistribution layer and is electrically connected to the redistribution layer.

According to an embodiment of the present disclosure, forming the thermal dissipation connections and forming the conductive connections are performed in a same process/step.

According to an embodiment of the present disclosure, the method of manufacturing the chip package further includes forming an insulating layer covering the light-shielding dummy conductive layers, the redistribution layer, or a combination thereof after forming the light-shielding dummy conductive layers and the redistribution layer.

According to an embodiment of the present disclosure, the method of manufacturing the chip package further includes slicing the wafer along a scribe line to form multiple chip packages.

According to an embodiment of the present disclosure, the method of manufacturing the chip package further includes performing a thinning process to the lower surface of the substrate after providing the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a chip package, in accordance with an embodiment of the present invention;

FIG. 2 illustrates a top view of a lower surface of a substrate of a chip package, in accordance with an embodiment of the present invention; and

FIGS. 3A to 3F illustrate cross-sectional views of a chip package at various stages of fabrication, in accordance with an embodiment of the present invention.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To solve the problems described in the background section, the present invention provides a chip package including a substrate, a conductive layer, and multiple thermal dissipation connections. The substrate includes a light-sensing region. The conductive layer includes a light-shielding dummy conductive layer substantially aligned with the light-sensing region to avoid light leakage. The thermal dissipation connections are disposed at a lower surface of the substrate to assist thermal dissipation. Accordingly, the chip package in the present disclosure can solve the problems, such as light leakage and bad thermal dissipation, described in the background section. The detailed descriptions of chip packages in various embodiments are described in the following.

The chip package in the present invention may be applied to various integrated circuits electronic components including active or passive elements, digital or analog circuits, such as optoelectronic devices, micro electro mechanical systems (MEMS), micro fluidic systems, and physical sensors for detecting physical characteristics such as detecting heat, light, or pressure. In particular, a wafer level package (WLP) process may be performed to package semiconductor chips which include image sensor devices, light-emitting diodes (LEDs), solar cells, RF circuits, accelerators, gyroscopes, micro actuators, surface acoustic wave devices, pressure sensors, and ink printer heads. The aforementioned wafer level package process is first packaged at the wafer level and then sliced into individual chip package. However, in a specific embodiment, separated semiconductor chips may be, for example, redistributed on a carrier wafer for a subsequent packaging process, which may be called a wafer level package process.

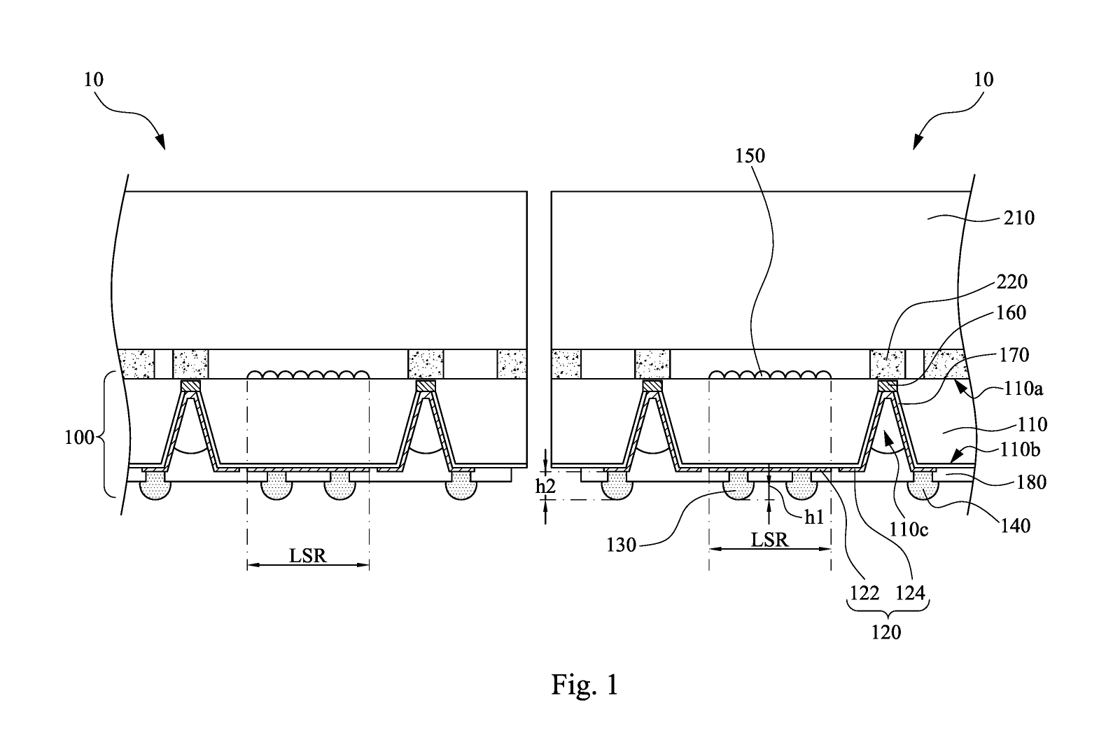

FIG. 1 is an exemplary cross-sectional view of a chip package, in accordance with some embodiments of the present invention. Please referring to FIG. 1, the chip package 10 includes a substrate 110, a conductive layer 120, and multiple thermal dissipation connections 130. In the embodiment, the chip package 10 is, for example but not limited to, an image sensor package.

The substrate 110 may be, for example, Si substrate or other semiconductor substrate, such as Si, Ge, or III-V element substrate. The substrate 110 have an upper surface 110a and a lower surface 110b opposite to each other, and a conductive pad region 160 underneath the upper surface 110a. The material of the conductive pad region 160 may be Al, Cu, Au, other suitable metals, or a combination thereof. In parts of embodiments in the present invention, the substrate 110 includes a semiconductor element, an inter-layer dielectric (ILD), an inter-metal dielectric (IMD), a passivation layer, and an metal interconnect structure. It should be noticed that conductive pad region 160 is the metal interconnect structure in the substrate 110, which has a plurality of metal layers arrayed in parallel and a via connected to these metal layers. The inter-metal dielectric is disposed between the metal layers and the via penetrates the inter-metal dielectric to be electrically connected to the metal layers. Wherein the semiconductor elements may be, for example, active elements, passive elements, digital, or analog electronic elements of integrated circuits electronic elements.

The substrate 110 includes a light-sensing region (LSR). In an embodiment, the chip package 10 further includes a light-receiving structure 150 disposed over the surface 110a of the light-sensing region (LSR) of the substrate to assist light-receiving of the image sensor. The conductive pad region 160 is electrically connected to the light-sensing region (LSR). Herein, each light-sensing region (LSR) is corresponding to two conductive pad regions 160 for simplifying the figures and descriptions. In an embodiment, the light-receiving structure 150 includes micro lens array.

The substrate 110 has a via 110c extending toward the upper surface 110a from the lower surface 110b and exposing the conductive pad region 160. The conductive layer 120 is disposed at the lower surface 110b of the substrate 110 and the conductive layer 120 has a light-shielding dummy conductive layer 122 and a redistribution layer 124. In an embodiment, the material of the conductive layer 120 includes Cu, Al, Au, Pt, Ni, other suitable metals, or a combination thereof. It should be noticed that the light-shielding dummy conductive layer 122 is substantially aligned with the light-sensing region (LSR) to prevent light leakage from occurring. The term “substantially aligned” herein refers to the vertical projection of the light-shielding dummy conductive layer 122 on the substrate 110 overlaps with the vertical projection of the light-sensing region (LSR) on the substrate 110. In an embodiment, the light-shielding dummy conductive layer 122 is substantially aligned with the light-receiving structure 150. In other words, the vertical projection of the light-shielding dummy conductive layer 122 on the substrate 110 overlaps with the vertical projection of the light-receiving structure 150 on the substrate 110. In this way, the light-shielding dummy conductive layer 122 can shield light effectively to prevent light leakage from occurring. Of course, the areas and relative positions of the light-shielding dummy conductive layer 122 and the light-receiving structure 150 can be properly adjusted to effectively prevent light leakage. Therefore, the present disclosure is not limited to what shown in the FIG. 1.

The thermal dissipation connections 130 are disposed underneath the lower surface 110b of the substrate 110. In an embodiment, the thermal dissipation connections 130 are floating and disposed underneath the light-shielding dummy conductive layer 122. In an embodiment, the thermal dissipation connections 130 are in contact with the light-shielding dummy conductive layer 122 to transmit heat generated during chip operation to the external through the light-shielding dummy conductive layer 122 and the thermal dissipation connections 130. In an embodiment, the thermal dissipation connections 130 are solder balls, conductive bumps, or other suitable thermal dissipation connection structures. The thermal dissipation connections 130 may have any shape, such as circular, ellipse, square, rectangular, or other suitable shapes.

In an embodiment, the redistribution layer 124 of the conductive layer 120 is apart from the light-shielding dummy conductive layer 122. In other words, the redistribution layer 124 and the light-shielding dummy conductive layer 122 are on the same level without electrical connection therebetween. Furthermore, the redistribution layer 124 is further extending to the through via 110c and in contact with the conductive pad region 160 to be electrically connected to the conductive pad region 160 so as to form a through silicon via (TSV) structure.

In an embodiment, the chip package 10 further includes multiple conductive connections 140 disposed underneath and electrically connected to the redistribution layer 124. It should be noticed that the vertical projection of the conductive connections 140 and the vertical projection of the through via 110c are not overlapped. The conductive connections may be electrically connected to other elements to perform signal-in and signal-out process. In an embodiment, the height (h1) of the top surface of each of the thermal dissipation connections 130 is substantially as same as the height (h2) of the top surface of each of the conductive connections 140. In other words, the height of the thermal dissipation connections 130 is equal to the height of the connective connections 140, which can enhance the image quality. Furthermore, the thermal dissipation connections 130 can support the chip. In an embodiment, the thermal dissipation connections 130 and the conductive connections 140 are solder balls.

In an embodiment, the chip package 10 further includes an insulating layer 170 disposed underneath the lower surface 110b and sandwiched between the conductive layer 120 and the substrate 110, and the insulating layer 170 further extends into the through via 110c and covers sidewalls of the through via 110c. The insulating layer 170 is used to isolate the substrate 110 and the conductive layer 120, and may be made of, for example, epoxy, solder-resisting material, or other suitable insulating materials such as silicon oxide, silicon nitride, silicon oxynitride, metal oxides, or a combination thereof.

In an embodiment, the chip package 10 further includes a protective layer 180 disposed underneath the conductive layer 120 and covers the conductive layer 120. In an embodiment, the protective layer 180 has multiple openings (not labeled), and the thermal dissipation connections 130 and the conductive connections 140 are disposed within the openings of the protective layer 180.

In an embodiment, the chip package 10 further includes a transparent substrate 210 disposed on the upper surface 110a of the substrate 110, which is used as a supporting structure in wafer-level package (WLP) process. The material of the transparent substrate 210 may be, for example, glass, quartz, opal, plastic, or other suitable transparent material. Furthermore, the chip package 10 may further includes a spacer layer 220 sandwiched between the upper surface 110a of the substrate 110 and the transparent substrate 210 to define multiple cavities (not labeled) where various elements can be disposed. In an embodiment, the cavities are places where the light-receiving structure 150 is disposed.

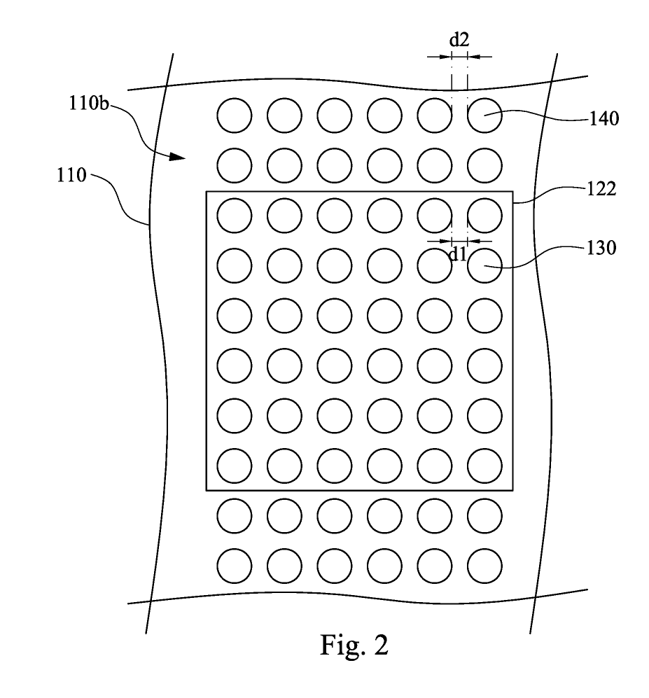

FIG. 2 is an exemplary top view of the lower surface 110b of the substrate 110 of a chip package, in accordance with some embodiments of the present invention. In the embodiment, the thermal dissipation connections 130 are disposed on the light-shielding dummy conductive layer 122. The thermal dissipation connections 130 are solder balls and are arranged in a solder ball array. The conductive connections 140 are also solder balls, and are arranged in another solder ball array. In the embodiment, the spacing (d1) between two adjacent solder balls in the array of the thermal dissipation connections 130 is substantially as same as the spacing (d2) between two adjacent solder balls in the array of the conductive connections 140. Of course, in other embodiments, relationships of kinds, arrays (such as random arrangement or regular arrangement, and the regular arrangement may be, for example, linear arrangement or staggered arrangement), sizes and spacing, of the thermal dissipation connections 130 and the conductive connections 140 can be adjusted properly as well to meet requirements of practical applications. Therefore, the present disclosure is not limited to what shown in the FIG. 2.

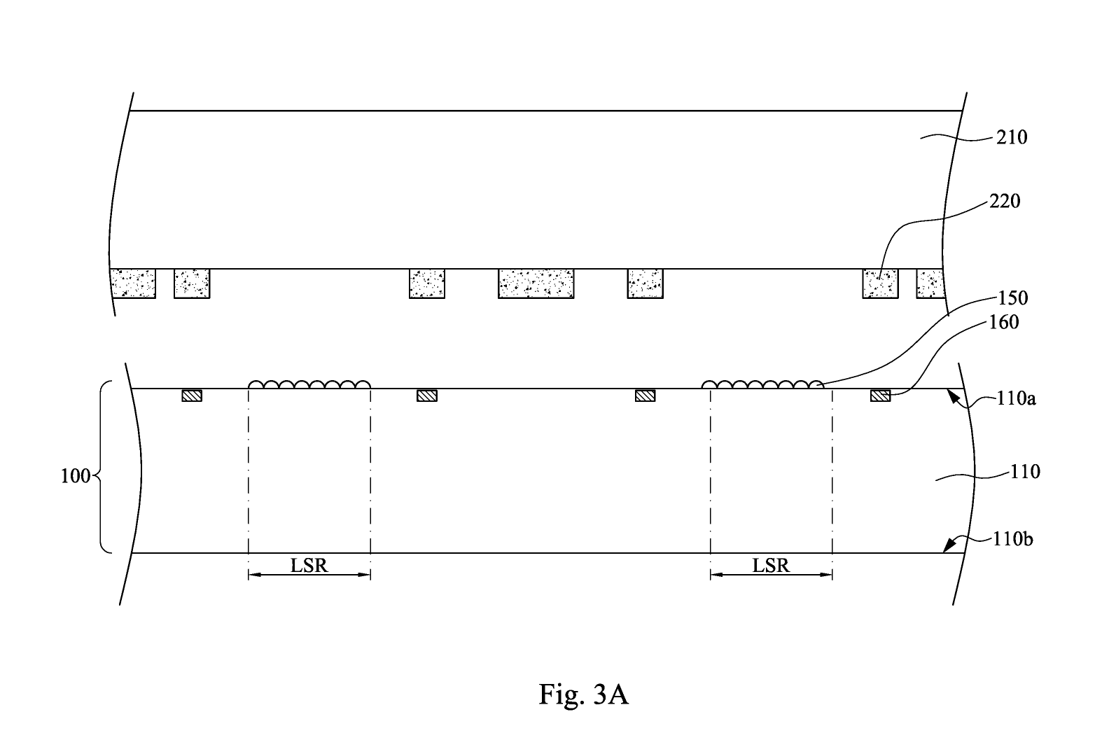

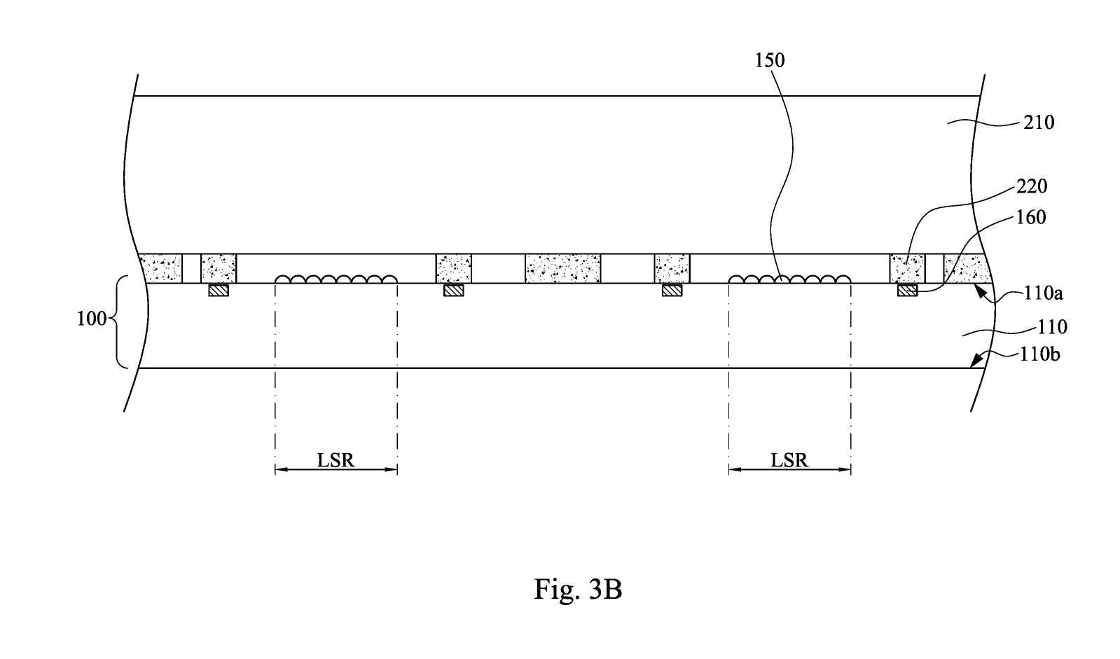

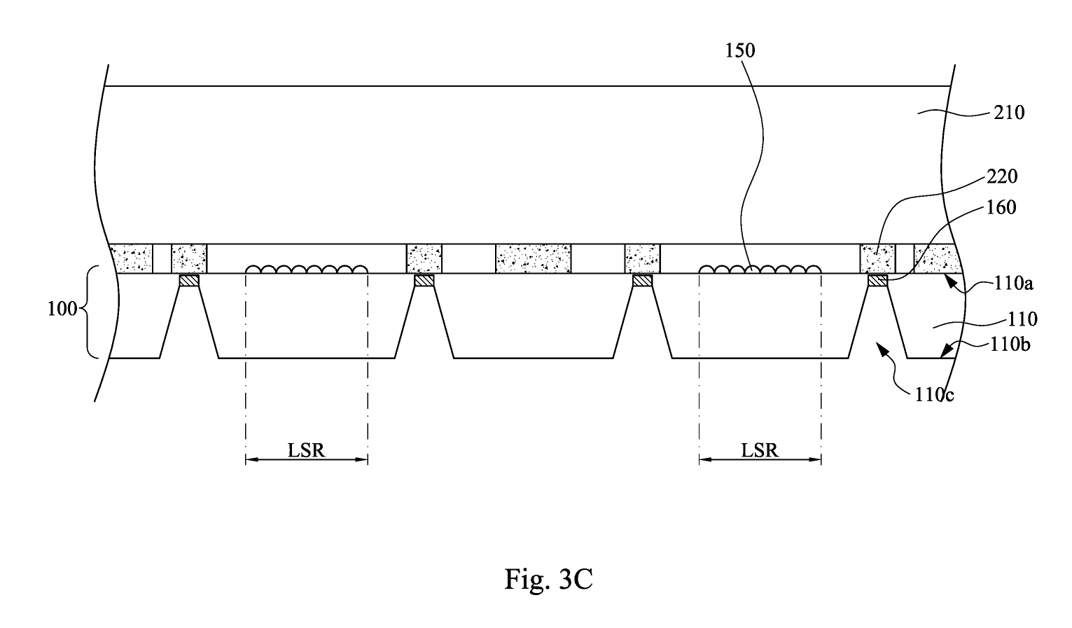

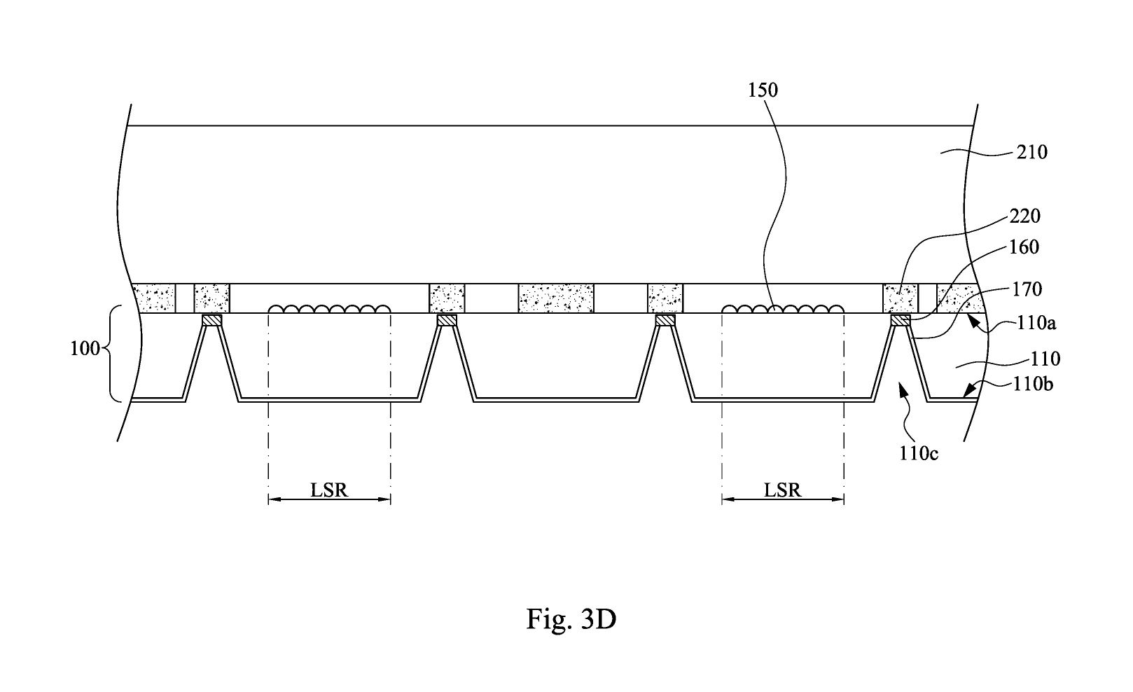

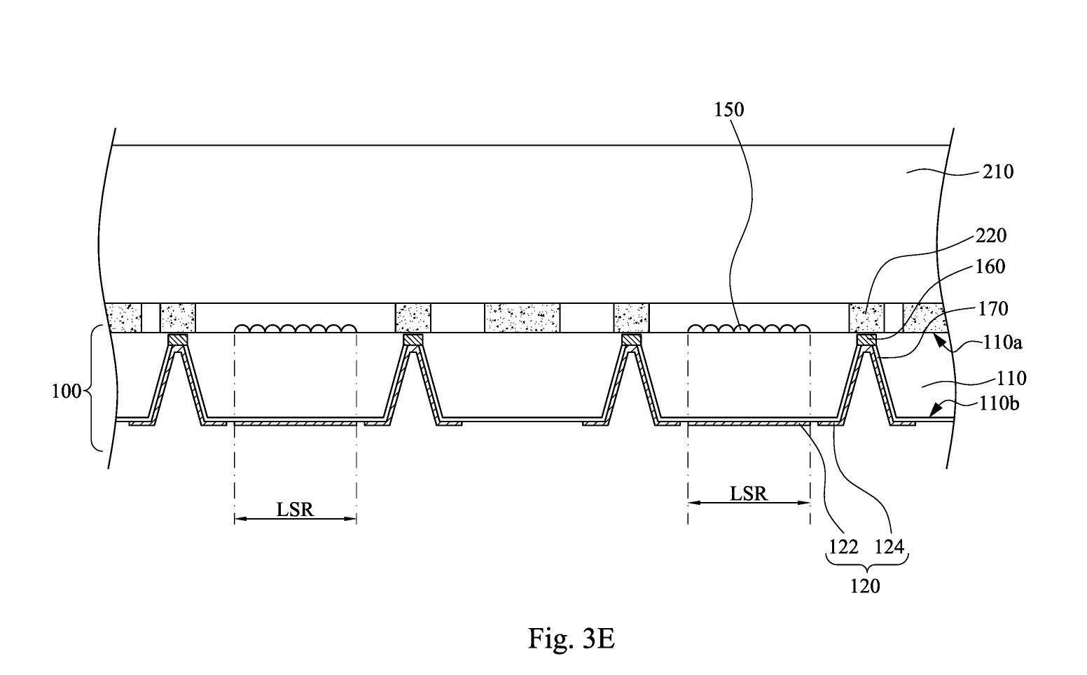

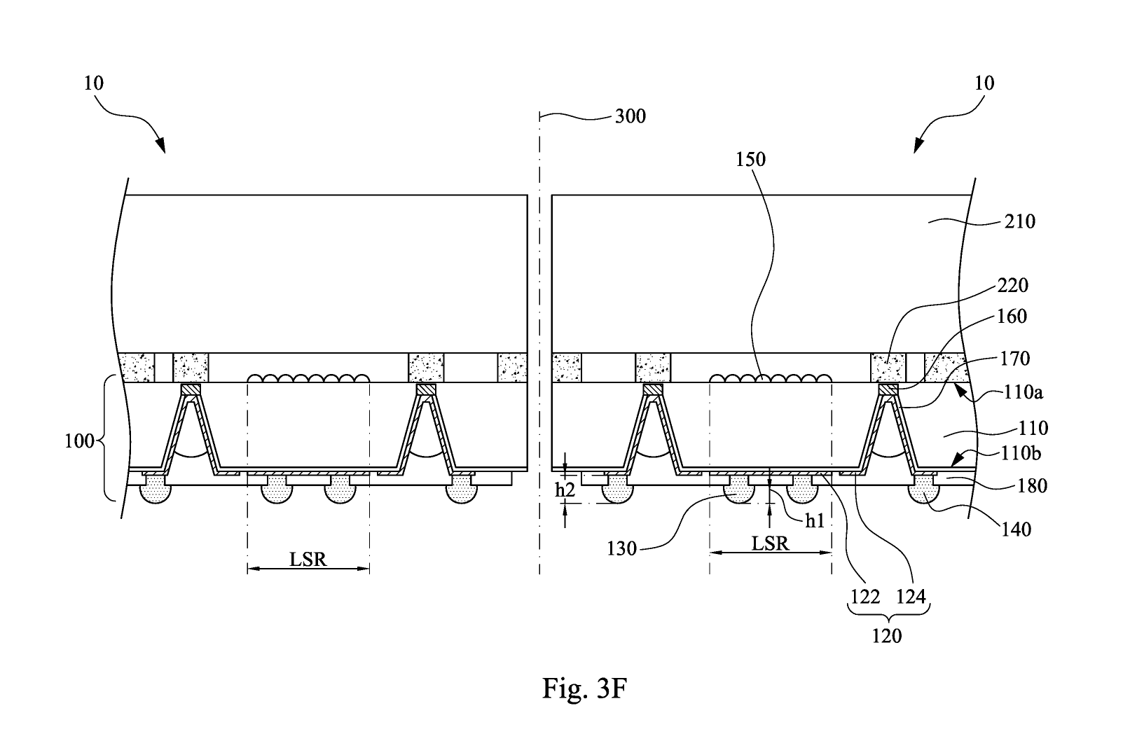

FIGS. 3A to 3F are exemplary cross-sectional views of a chip package at different stages of fabrication, in accordance with various embodiments. As shown in FIG. 3A, a wafer 100 including a substrate 110 and at least a conductive pad region 160 is provided. The wafer 100 has a plurality of chip regions thereon, which will be sliced into a plurality of chip packages as same as the chip package 10 illustrated in FIG. 1. In some embodiments of the present invention, the substrate 110 includes a semiconductor elements, an inter-layer dielectric (ILD), an inter-metal dielectrics (IMD), a passivation layer, and an interconnect metal structure. For simplifying figures, only one planarized substrate is represented. It should be noticed that the conductive pad region 160 is the interconnect metal structure of the substrate 110, which has a plurality of metal layers arranged in parallel and a via in contact with the metal layers. The inter-metal dielectric (ILD) is disposed between the metal layers and the via penetrates the inter-metal dielectric to be electrically connected to the adjacent metal layers.

The substrate 110 may be, for example, Si substrate or other semiconductor substrate, such as Si, Ge, or III-V substrate. The substrate 110 has an upper surface 110a and a lower surface 110b opposite to each other. Furthermore, the substrate includes multiple light-sensing regions (LSR). The conductive pad region 160 is disposed underneath the upper surface 110a of the substrate 110 and is out of the light-sensing region (LSR), wherein the material of the conductive pad region 160 may be Al, Cu, Au, other suitable metals, or a combination thereof. In an embodiment, the wafer 100 further includes multiple light-receiving structures 150 disposed over the upper surface 110a of the light-sensing region (LSR) of the substrate 110 to assist light-receiving of the image sensor. In an embodiment, the light-receiving structure 150 includes micro lens array.

Furthermore, a transparent substrate 210 and a spacer layer 220 are disposed over the wafer 100. The transparent substrate 210 can be used as a supporting structure in wafer-level package (WLP) process. The material of the transparent substrate 210 may be, for example, glass, quartz, opal, plastic, or other suitable transparent material. The spacer layer 220 is sandwiched between the upper surface 110a of the substrate 110 and the transparent substrate 210 to define multiple cavities (not labeled), where various elements can be disposed. In an embodiment, the cavities are a place where the light-receiving structure 150 is disposed.

In an embodiment, as shown in FIG. 3B, a thinning process is performed on the lower surface 110b of the substrate 110 after providing the wafer 100 to thin down the thickness of the substrate to a pre-determined thickness. Generally, the thinning process may include etching, milling, grinding, or polishing.

Then, as shown in FIG. 3C, a portion of the substrate 110 is removed to form a through via 110c exposing the conductive pad region 160. In an embodiment, the lower surface 110b of the substrate 110 is etched to form the through via 110c extending from the lower surface 110b to the upper surface 110a. The through via 110c may be a tilted opening or a vertical opening. The shape of the through via 110c in a top view may be any shapes, such as circular, ellipse, square, rectangular, or other suitable shapes. The through via 110c is formed by, for example but not limited to, photolithography process. The etching process may be, for example, dry-etching or wet-etching.

As shown in FIG. 3D, an insulating layer 170 is formed underneath the lower surface 110b of the substrate 110 and covers sidewalls of the through via 110c. The insulating layer 170 is used to isolate the substrate 110 and subsequently-formed conductive layers. The material of the insulating layer 170 may be, for example, epoxy, solder-resisting material, or other suitable insulating material, such as silicon oxide, silicon nitride, silicon oxynitride, metal oxide, or a combination thereof. The insulating layer 170 may be formed by, for example, a coating process or a deposition process. The coating process may be, for example, spin coating, spray coating, or curtain coating. The deposition process may be, for example, liquid deposition, physical vapor deposition, chemical vapor deposition, low pressure chemical vapor deposition, plasma enhanced chemical vapor deposition, rapid thermal chemical vapor deposition, or normal pressure chemical vapor deposition.

As shown in FIG. 3E, multiple light-shielding dummy conductive layers 122 and redistribution layers 124 are formed underneath the insulating layer 170 after forming the insulating layer 170 and the light-shielding dummy conductive layers 122 and the redistribution layers 124 are separated from each other as shown in FIG. 3E. Each of the light-shielding dummy conductive layers 122 are respectively substantially aligned with the light-sensing region (LSR) to prevent light leakage from occurring. The redistribution layers 124 are electrically connected to the conductive pad region 160 to form a through substrate via electrode structure (not shown). For example, a conductive material layer (not shown) may be deposited by a carpet-covered deposition first, followed by a photolithography process to pattern the conductive material layer and form the multiple light-shielding dummy conductive layers 122 and the redistribution layers 124 underneath the insulating layer 170, and the light-shielding dummy conductive layers 122 are separated from the redistribution layers 124. Of course, the light-shielding dummy conductive layers 122 and the redistribution layers 124 may be formed by other processes, such as screen printing, inkjet printing, or laser ablation.

As shown in FIG. 3F, a protective layer 180 covering the light-shielding dummy conductive layers 122, the redistribution layers 124, or both is formed after forming the light-shielding dummy conductive layers 122 and the redistribution layers 124. Then, a portion of the protective layer 180 is removed to form multiple openings (not labeled) exposing portions of the light-shielding dummy conductive layers 122 and portions of the redistribution layers 124. The openings are a place where subsequently-formed thermal dissipation connections and conductive connections are disposed. The material of the protective layer 180 may be, for example but not limited to, solder-resisting material, such as epoxy. And a portion of the protective layer 180 flows into but not fulfills the through via 110c.

Please continue referring to FIG. 3F, multiple thermal dissipation connections 130 are formed underneath the light-shielding dummy conductive layers 122 after forming the protective layer 180. As mentioned before, the protective layer 180 has multiple openings exposing the light-shielding dummy conductive layers 122 and the redistribution layers 124, and the thermal dissipation connections 130 are formed within the openings to be in contact with the light-shielding dummy conductive layers 122. Wherein, the thermal dissipation connections 130 may be, for example, solder balls, conductive bumps, or other suitable thermal dissipation structures. The thermal dissipation connections 130 may have any shape, such as circular, ellipse, square, rectangular, or other suitable shapes. In an embodiment, the thermal dissipation connections 130 are floating and formed underneath the light-shielding dummy conductive layers 122. Therefore, the heat generated during chip operation can be transmitted to the external through the light-shielding dummy conductive layers 122 and the thermal dissipation connections 130.

Please continue referring to FIG. 3F, the conductive connections 140 are formed underneath and connected to the redistribution layers 124 within the openings to be electrically connected to the redistribution layers 124. In an embodiment, the thermal dissipation connections 130 and the conductive connections 140 are formed in the same process/step. The conductive connections 140 may be electrically connected to other elements to perform signal-input or signal-output process. In an embodiment, the thermal dissipation connections 130 and the conductive connections 140 are both solder balls.

As shown in FIG. 1, the wafer 100 is further sliced along the scribe line 300 to separate multiple chip regions of the wafer 100 after the thermal dissipation connections 130 are formed. Then, the spacer layer 220 and the transparent substrate 210 are further sliced along the scribe line 300 to form two individual chip packages 10.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a substrate comprising a light-sensing region and having an upper surface and a lower surface opposite to each other;
a conductive layer disposed at the lower surface of the substrate and comprising a light-shielding dummy conductive layer substantially aligned with the light-sensing region; and
a plurality of thermal dissipation connections disposed underneath the lower surface of the substrate.

2. The chip package of claim 1, further comprising a light-receiving structure disposed at the upper surface of the light-sensing region of the substrate.

3. The chip package of claim 1, wherein the thermal dissipation connections are floating and disposed underneath the light-shielding dummy conductive layer.

4. The chip package of claim 3, wherein the thermal dissipation connections are in contact with the light-shielding dummy conductive layer.

5. The chip package of claim 1, further comprising an insulating layer sandwiched between the substrate and the conductive layer.

6. The chip package of claim 1, wherein the conductive layer further comprises a redistribution layer separated from the light-shielding dummy conductive layer.

7. The chip package of claim 6, further comprising a plurality of conductive connections disposed underneath and electrically connected to the redistribution layer.

8. The chip package of claim 7, wherein a height of each top surface of the thermal dissipation connections is substantially equal to a height of each top surface of the conductive connections.

9. The chip package of claim 1, wherein the thermal dissipation connections are solder balls.

10. The chip package of claim 9, wherein the thermal dissipation connections are arranged in a solder ball array.

11. A method of manufacturing a chip package, the method comprising:
providing a wafer comprising a substrate and at least a conductive pad region, the substrate comprising a plurality of light-sensing regions and having an upper surface and a lower surface opposite to each other, the conductive pad region is disposed underneath the upper surface of the substrate out of the light-sensing regions;
removing a portion of the substrate to form a through via exposing the conductive pad region;
forming an insulating layer underneath the lower surface of the substrate and covering a sidewall of the through via;
forming a plurality of light-shielding dummy conductive layers and a redistribution layer separated from each other and underneath the insulating layer, the light-shielding dummy conductive layers are respectively substantially aligned with the light-sensing regions, the redistribution layer is electrically connected to the conductive pad region; and
forming a plurality of thermal dissipation connections underneath the light-shielding dummy conductive layers, the redistribution layer, or a combination thereof.

12. The method of claim 11, wherein the thermal dissipation connections are floating and formed underneath the light-shielding dummy conductive layers.

13. The method of claim 11, further comprising forming a conductive connection underneath and electrically connected to the redistribution layer.

14. The method of claim 13, wherein forming the thermal dissipation connections and forming the conductive connections are performed at a same process step.

15. The method of claim 11, further comprising forming a protective layer covering the light-shielding dummy conductive layers, the redistribution layer, or a combination thereof after forming the light-shielding dummy conductive layer and the redistribution layer.

16. The method of claim 15, further comprising slicing the wafer along a scribe line to form a plurality of chip packages.

17. The method of claim 11, further comprising performing a thinning process to the lower surface of the substrate after providing the wafer.
